(19) United States
(12) Patent Application Publication
(10) Pub. No.: US 2011/0149431 A1
(43) Pub. Date: Jun. 23, 2011

(54) Fall Detection Apparatus, Magnetic Disk Apparatus, and Portable Electronic Apparatus

(75) Inventor: Akihiko Shibata, Nagaokakyo-shi (JP)

(73) Assignee: Murata Manufacturing Co., Ltd.

(21) Appl. No.: 13/011,126

(22) Filed: Jan. 21, 2011

Related U.S. Application Data
(63) Continuation of application No. PCT/JP2009/061559, filed on Jun. 25, 2009.

(30) Foreign Application Priority Data
Jul. 23, 2008 (JP) 2008-189786

(51) Int. Cl. G11B 21/02; G01P 15/00; H05K 5/00

(52) U.S. Cl. 360/75; 73/514.01; 361/679.01; G9B/21.003

(57) ABSTRACT

A fall detection apparatus that detects values ax, ay, and az in accordance with acceleration in three mutually orthogonal axes (x, y, and z). Among these detected values, the fall detection apparatus determines values dxy and dzy which are the differences between the detected value for a reference axis, e.g., the y-axis, as well as the other detected values. A falling state signal is then generated when a preliminary determination state in which the determination values are within predetermined ranges continues for a predetermined time or longer.

### CROSS REFERENCE TO RELATED APPLICATIONS

The present application is a continuation of International Application No. PCT/JP2009/061559, filed Jun. 25, 2009, which claims priority to Japanese Patent Application No. JP2008-189786, filed Jul. 23, 2008, the entire contents of each of these applications being incorporated herein by reference in their entirety.

### FIELD OF THE INVENTION

The present invention relates to fall detection apparatuses for detecting whether or not an apparatus is in a falling state on the basis of acceleration, and magnetic disk apparatuses and portable apparatuses including the fall detection apparatus.

### BACKGROUND OF THE INVENTION

To date, an apparatus that detects the falling state of an apparatus is disclosed in Patent Document 1.

FIG. 1 illustrates how the output (az) of the Z-axis direction acceleration sensor described in Patent Document 1 changes from 1 to approximately zero. The configuration described in Patent Document 1 includes a computation circuit for calculating the magnitude of acceleration on the basis of the output signal of an acceleration sensor, a comparator circuit for determining whether or not the magnitude of acceleration has become close to zero, and a continuation determining circuit for determining whether or not, after the acceleration became approximately zero, this state has continued for a predetermined period of time. It is determined whether or not a magnetic disk apparatus, for example, is in free fall on the basis of whether or not the state in which all the acceleration components for the X-axis, Y-axis, and Z-axis are approximately zero has continued for a reference continuation time.

In this manner, the determination circuit determines that the state in which all the outputs for the three axes are approximately zero for the reference continuation time corresponds to a “falling” state.

[Patent Document 1] Japanese Patent No. 3441668

However, in the method of fall detection described in Patent Document 1, the state of an acceleration sensor output being approximately zero for each of the three axes needs to correspond to a gravity-free state for each axis. Hence, this method requires an acceleration sensor whose output reliably shows zero in a gravity-free state during falling.

However, the characteristics of acceleration sensors vary due to, for example, manufacturing variations, changes with temperature, or changes with time. Hence, the determination method described above has the following problems.

(1) Fall determination becomes impossible when the characteristics variation of an acceleration sensor exceeds a certain threshold.

(2) Setting the threshold to be a larger value, taking into consideration the characteristics variation of the acceleration sensor, would result in an increase in the number of malfunctions that cause a non-falling case to be erroneously determined to be a “falling” case.

(3) Although the characteristics variation of the acceleration sensor can be corrected (compensated) for using one of a number of methods, this requires a separate compensation circuit, preventing a reduction in the size and cost of an apparatus.

### SUMMARY OF THE INVENTION

Accordingly, the present invention provides a small-size low-cost fall detection apparatus, and a magnetic disk apparatus and portable apparatus including the fall detection apparatus, in which the problems of the characteristics variations of acceleration sensors are solved, thereby preventing fall detection from becoming impossible and preventing malfunctions.

To solve the above-described problems, the present invent is configured as follows.

(1) A fall detection apparatus that detects a fall on the basis of an output signal of an acceleration sensor, includes: acceleration detecting means configured to obtain detected values in accordance with acceleration in three axis directions orthogonal to one another; and fall determination output means configured to obtain a determination value which is, among the detected values in the three axis directions obtained by the acceleration detecting means, a difference between the detected value corresponding to a reference axis direction and the detected value not corresponding to the reference axis direction, and configured to generate a falling state signal when a preliminary determination state in which the determination value is within a predetermined range continues for a predetermined continuation time or longer.

The detected values obtained by the acceleration detecting means are values determined in accordance with steady state errors, such as offsets, and acceleration values. In a falling state, although the detected values obtained by the acceleration sensors may not be substantially zero, the acceleration sensors continue to output constant values corresponding to an acceleration of zero, and the determination value continues to be a value within a predetermined range. Hence, the falling state signal output by the fall determination output means indicates a falling state.

(2) The fall detection apparatus includes falling state cancelling means configured to cancel the falling state signal when the preliminary determination state continues for a time exceeding an upper limit time longer than the continuation time.

Even if the actual state is a 1 G state and is not a falling state, the detected value obtained by the acceleration sensor continues to be a constant value when the acceleration sensor is in a state of rest. Hence, also in this case, the determination value may happen to continuously be a value within the predetermined range. At this time, the falling state signal is generated and a magnetic disk apparatus or portable apparatus containing the fall detection apparatus performs shock preparation operation. This is a safe side malfunction rather than a fatal malfunction in which the falling state signal is not generated in spite of the apparatus being in a state of actually falling.

When the current state is a 1 G state rather than a falling state, the preliminary determination state continues for a longer time than the falling state. Hence, the falling state signal is cancelled by the falling state cancellation means. Accordingly, fall determination becomes possible again.

(3) The fall detection apparatus includes: steady state detected value storing means configured to store the detected values for the three axis directions at the time when the falling state cancelling means performs the cancellation; and prohibiting means configured to prohibit fall detection determination or prohibit outputting of a fall determination result when the detected values for the three axis directions are equal to or, within a predetermined value range, nearly equal to the values stored in the steady state detected value storing means.

When a 1 G state continues, the generation of the falling state signal performed by the fall determination output means and the cancellation of the falling state signal performed by the falling state cancelling means are repeated. However, when the steady state detected value storing means once stores the detected values obtained by the acceleration sensor in a 1 G state, the fall detection determination or the outputting of a fall determination result is prohibited by the prohibiting means. Hence, even when the 1 G state continues, after the falling state signal has been first generated by the fall determination output means and the falling state signal has been cancelled by the falling state cancelling means, the falling state signal is not generated again.

(4) A magnetic disk apparatus includes: the fall detection apparatus; a head configured to perform data recording or reading for a magnetic disk; and head retracting means configured to retract the head to a retraction area when the fall detection apparatus generates the falling state signal.

This configuration allows the magnetic disk apparatus to be protected against a fall.

(5) A portable electronic apparatus including the fall detection apparatus and a device configured to allow shock protection processing to be performed therefor, includes: shock protection processing means configured to perform shock protection processing for the device when the fall detection apparatus generates the falling state signal.

This configuration allows the safety of the portable electronic apparatus to be enhanced by effectively controlling the device which allows shock protection processing to be performed therefor.

According to the present invention, fall detection is possible even when the output signal of an acceleration sensor includes a steady state error, such as an offset. In addition, by providing the falling state cancelling means, even when a 1 G state is erroneously determined to be a “falling state”, fall detection becomes possible again since the falling state signal is cancelled afterward.

### BRIEF DESCRIPTION OF THE DRAWINGS

FIG. 1 illustrates how the output (az) of the Z-axis direction acceleration sensor described in Patent Document 1 changes from 1 to approximately zero.

FIG. 2 is a block diagram of a configuration of a fall detection apparatus according to a first embodiment.

FIG. 3 illustrates examples of the detected values obtained by the acceleration sensor 60 for respective axes versus elapsed time before and after a fall.

FIG. 4 is a flowchart of processing steps for fall detection performed by the controller 74 illustrated in FIG. 2 on the basis of the output values of the A/D converter 72.

FIG. 5 is a flowchart of processing steps performed by a controller of a fall detection apparatus according to a second embodiment.

FIG. 6 is a flowchart of processing steps performed by a controller of a fall detection apparatus according to a third embodiment.

FIG. 7 is a block diagram of a configuration of a magnetic disk apparatus, such as a hard disk drive apparatus.

FIG. 8 is a block diagram of a configuration of a mobile electronic apparatus containing a hard disk drive, such as a notebook PC or music/video reproduction apparatus.

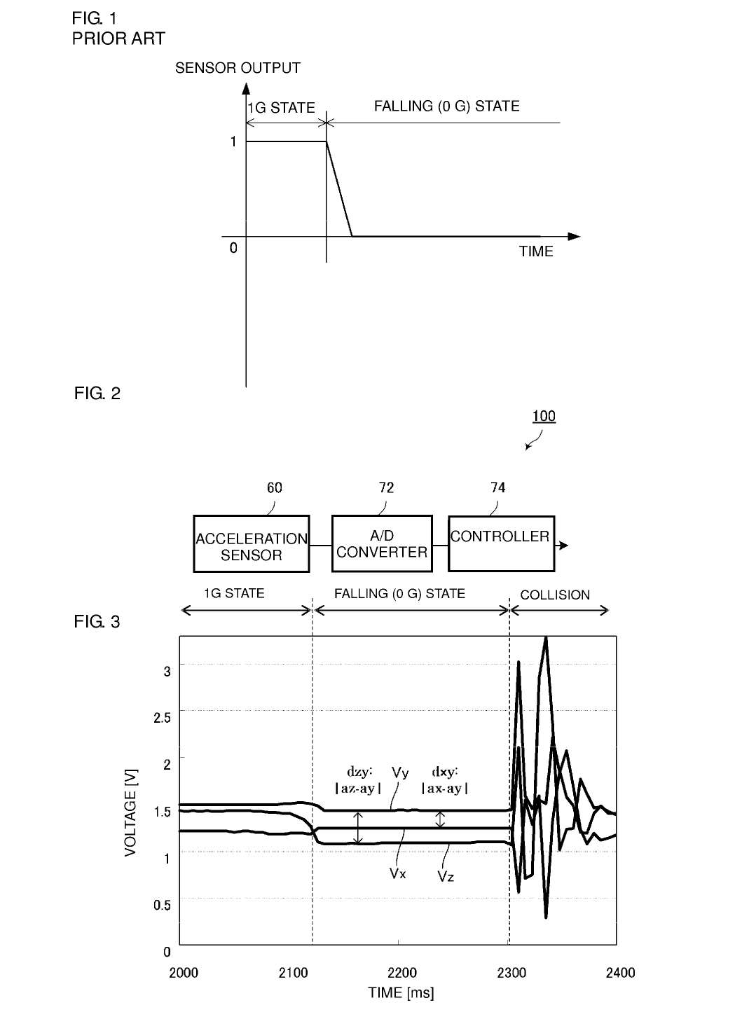

### DETAILED DESCRIPTION OF THE INVENTION

### First Embodiment

FIG. 2 is a block diagram of the configuration of a fall detection apparatus according to a first embodiment. A fall detection apparatus 100 includes an acceleration sensor 60 that detects acceleration and outputs an analog voltage signal corresponding to the acceleration, an A/D converter 72 that converts the output voltage of the acceleration sensor 60 into digital data, and a controller 74 that performs fall detection on the basis of the output data of the A/D converter 72 and outputs the detection result to an external apparatus (host apparatus). Here, the acceleration sensor 60 corresponds to “acceleration detecting means” according to the present invention.

To detect a fall also in the case where falling directions are not fixed, acceleration components in three dimensional directions are detected and fall detection is performed on the basis of those results. The acceleration sensor 60 is formed of three acceleration sensors respectively detecting acceleration components in the X-axis, Y-axis, and Z-axis directions orthogonal to one another. The A/D converter 72 converts the output voltages of the respective acceleration sensors into digital data and outputs the data as detected acceleration values ax, ay, and az for respective axis directions. The controller 74 performs fall determination in accordance with the processing described below.

Examples of various acceleration sensors that can be used as the acceleration sensor 60 include a piezoelectric, piezo-resistance, and capacitive acceleration sensors.

FIG. 3 illustrates examples of the output voltages Vx, Vy, and Vz of the acceleration sensor 60 and the detected values ax, ay, and az for respective axes versus elapsed time. Here, the vertical axis represents the detected values (voltages) for the respective axes of the acceleration sensor 60, in units of voltages, and the horizontal axis represents an elapsed time t [ms].

In a 1 G state, that is, in a steady state where falling has not yet started, the detected values (voltages) for the respective axes of the acceleration sensor 60 continue to be predetermined values. When a falling state (0 G) is entered at a point in time, the detected values (voltages) for the respective axes of the acceleration sensor 60 continue to be values corresponding to 0 G. Then, the outputs of the acceleration sensor 60 for the respective axes vary widely due to collision with a floor or the ground.

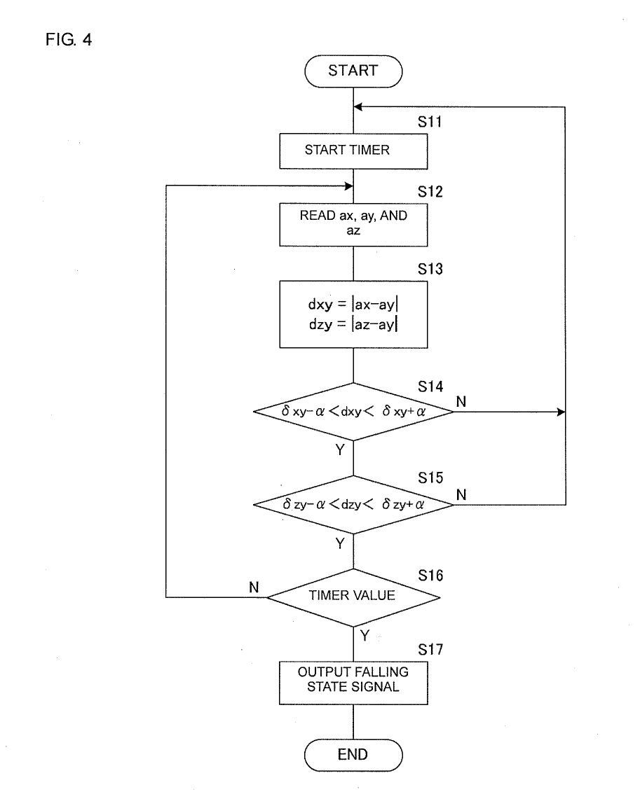

FIG. 4 is a flowchart of processing steps for fall detection performed by the controller 74 illustrated in FIG. 2 on the basis of the output values of the A/D converter 72.

In the figure, ax is a detected value (subsequent to A/D conversion of the acceleration sensor output voltage) obtained by the acceleration sensor for detecting the acceleration in the x-axis direction, ay is a detected value obtained by the acceleration sensor for detecting the acceleration in the y-axis direction, and az is a detected value obtained by the acceleration sensor for detecting the acceleration in the z-axis direction.

First, a timer is started (S11), and the detected values ax, ay, and az obtained by the acceleration sensor 60 are read (S12).

Then, the absolute value dxy of the difference between ax and ay, and the absolute value dzy of the difference between az and ay are obtained, with ay as a reference (S13). Then it is determined whether or not the absolute values dxy and dzy of the two difference values are respectively within δxy±α and δzy±α described later (S14, S15).

When dxy and dzy described above are stable as illustrated in FIG. 3, the determination results in both steps S14 and S15 are “Yes”, and steps S12 to S16 described above are repeated while a “preliminary determination state” continues for a predetermined continuation time T (S16→S12→ . . . ).

When the value of the timer reaches T described above, a falling state signal is output (S17).

Fall detection is performed in the above-described manner. According to the first embodiment, instead of observing a change in the detected value in accordance with an elapsed time, determination is performed every time on the basis of the absolute value of the difference between the detected values for two axes among the acceleration values for the three axes orthogonal to one another. Hence, high-response fall detection is realized without making the arithmetic operation cycle time short.

The detected values (ax, ay, az) obtained by the above-described acceleration sensor are represented by the relation (gx+δx, gy+δy, gz+δz) with respect to the actual acceleration (gx, gy, gz). Here, δ is an output variation in a gravity-free state specific to the sensor device. In other words,

(ax,ay,az)=(gx+δx,gy+δy,gz+δz).

The sensor output is (δx, δy, δz) even in the gravity-free state (gx=gy=gz=0). Hence, in the existing technique, when these values are larger than a threshold, the gravity-free state is not recognized as a falling state, or a compensation circuit is required to make these values zero.

In the first embodiment, with |ax−ay| and |az−ay| as determination values, it is determined that the current state is a falling state when the following state continues for the predetermined continuation time or more:

|δx−δy|−α<|ax−ay|<|δx−δy|+α (α>0)

and

|δz−δy|−α<|az−ay|<|δz−δy|+α

Hence, this determination utilizes the fact that the determination values described above logically become respectively |δx−δy| and |δz−δy| in a gravity-free state.

These |δx−δy| and |δz−δy| are respectively δxy and δzy illustrated in FIG. 4.

The process of this determination is described with reference to FIG. 3. Since the output of the acceleration sensor is not compensated for, the sensor outputs for the respective axes in a falling (0 G) state are different from one another. In the existing technique, such sensors cannot be used to perform fall determination, or it is necessary to adjust the sensor outputs to a 0 G reference voltage (for example, 1.25 [V]) using a compensation circuit.

Assuming |δx−δy|=0.19 [V], |δz−δy|=0.35 [V], and α=0.04 [V], determination is performed using the following reference ranges:

0.15<|ax−ay|<0.23, and

0.31<|az−ay|<0.39.

In a 1 G state in which the acceleration sensor is held in the air by hand,

|ax−ay|≈0.30 [V]

|az−ay|≈0.08 [V].

Since these values are out of the reference ranges, this state is not considered to correspond to a falling state.

On the other hand, when the sensor is put in a falling (0 G) state out of hand,

|ax−ay|≈0.20 [V]

|az−ay|≈0.36 [V].

These values are within the reference ranges. In this case, when the reference time has been set to be 100 [ms], a falling state signal can be generated before the sensor collides with a floor.

The output values (δx, δy, δz) of the acceleration sensor for the respective axes in a 0 G state can be obtained in advance by making the sensor for each axis be held horizontally. Hence, on the basis of these values, |δx−δy| and |δz−δy| described above can be fixed in advance.

Note that although the relative voltages of the x-axis and z-axis with the y-axis as a reference axis are used for the determination in the first embodiment, the reference axis may be the x-axis or z-axis.

Although the above description is for the output variation in a gravity-free state, the present embodiment is effective also for variation due to a change in temperature and a change with time, since the outputs for the respective axes similarly vary due to these changes in general. In other words, by letting this variation be Δ, the following relation is satisfied.

|(ax+Δ)−(ay+Δ)|=|ax−ay|

Hence, the influence of this variation is cancelled out. In this manner, since the influence of a change in temperature or a change with time is prevented, malfunctions caused by such influence are prevented, or a compensation circuit need not be provided.

### Second Embodiment

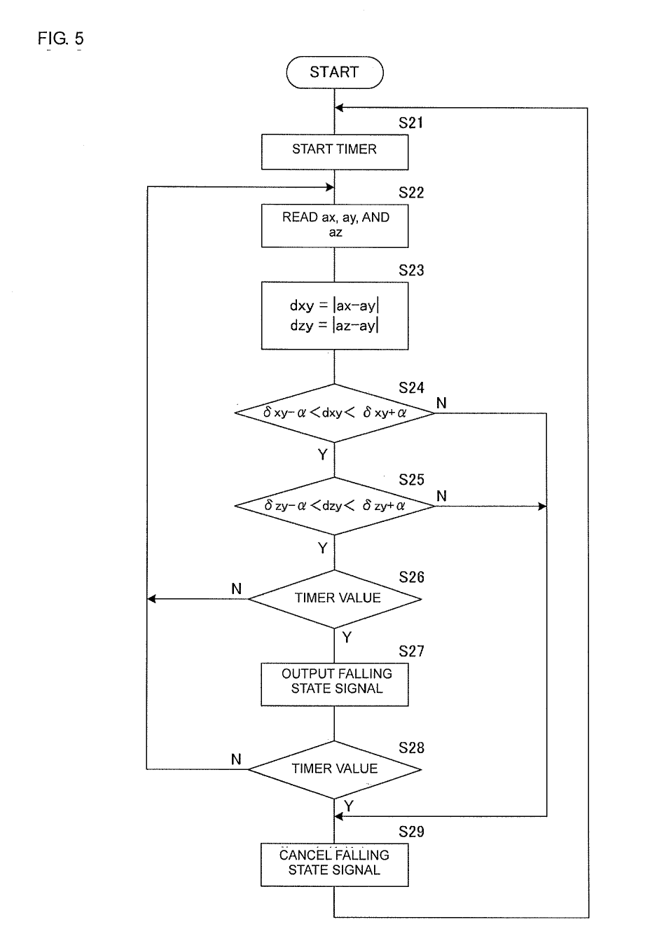

A fall detection apparatus according to a second embodiment will be described with reference to FIG. 5.

The block diagram of the configuration of the fall detection apparatus according to the second embodiment is the same as that illustrated in FIG. 2. FIG. 5 is a flowchart of processing steps performed by the controller 74 illustrated in FIG. 2. First, the timer is started (S21), and detected values ax, ay, and az obtained by the acceleration sensor 60 are read (S22).

Then, the absolute value dxy of the difference between ax and ay, and the absolute value dzy of the difference between az and ay are obtained, with ay as a reference (S23). Then it is determined whether or not the absolute values dxy and dzy of the two difference values are respectively within δxy±α and δzy±α (S24, S25). These ranges, δxy±α and δzy±α, are the same as those described in the first embodiment.

When the timer value has reached T1, a falling state signal is output (S26→S27).

Then, it is determined whether or not the timer value has reached an upper limit time T2, which is longer than T1 (S28). The steps S22 to S28 are repeated until the timer value reaches this upper limit time T2 (S28→S22→ . . . ).

When the timer value has exceeded the upper limit time T2, the falling state signal is cancelled (S29). Then, the timer is started again, and the same processing is performed (S28→S29→S21→ . . . ).

In addition, when dxy or dzy, which is the absolute value of the difference between the detected values for two axes, varies in such a manner as to exceed the range δxy±a or δzy±α after the falling state signal has been once output in step S27, it is determined that the current state is not a falling state (normal moving state or collision state after falling), and the falling state signal is cancelled (S24, S25→S29).

In this manner, in the fall detection apparatus according to the second embodiment, even when a fall state signal is output although the current state is a 1 G state, that is, not a falling state, the falling state signal is cancelled if the current state is actually not a falling (0 G) state, thereby preventing the falling state signal from being wrongly output continuously.

### Third Embodiment

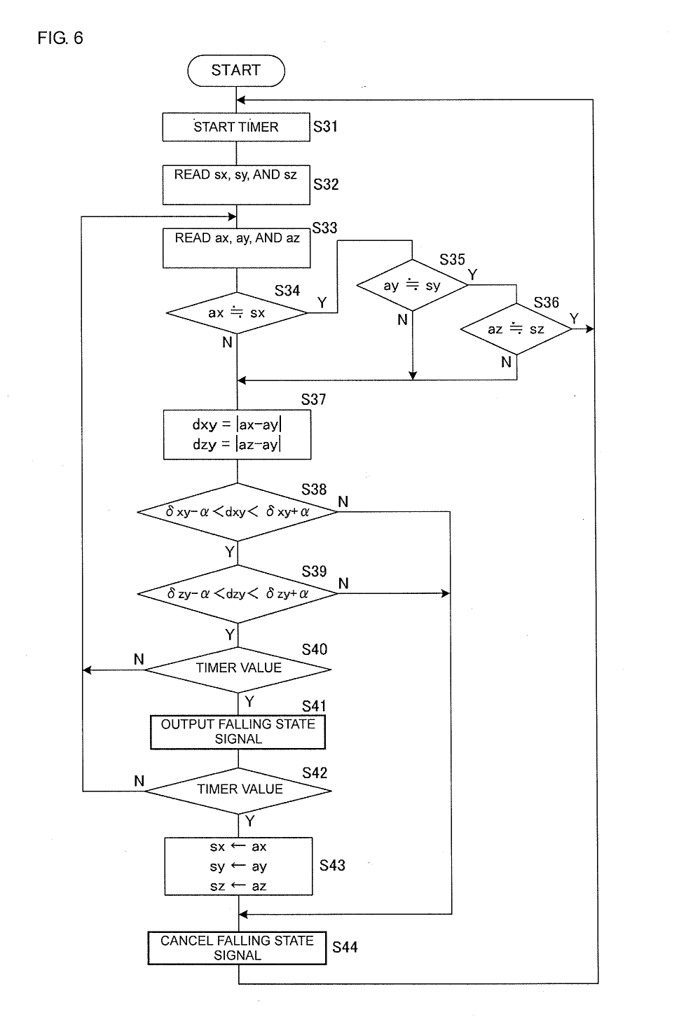

Referring to FIG. 6, sx, sy, and sz are data on the basis of which fall detection determination based on ax, ay, and az is prohibited or the output of a fall detection determination result is prohibited. When detected values for the three axes ax, ay, and az read in step S33 respectively are nearly equal to sx, sy, and sz within a predetermined error tolerance, subsequent processing for fall determination is not performed (S34→S35→S36→S31).

Then, the absolute value dxy of the difference between ax and ay, and the absolute value dzy of the difference between az and ay are obtained, with ay as a reference (S37). Then it is determined whether or not the absolute values dxy and dzy of the two difference values are respectively within δxy±α and δzy±α (S38, S39). These ranges, δxy±α and δzy±α, are the same as those described in the first and second embodiments.

When the timer value has reached T1 described above, a falling state signal is output (S40→S41).

Then, it is determined whether or not the timer value has reached an upper limit time T2, which is longer than T1 (S42). The steps S33 to S42 are repeated until the timer value reaches this upper limit time T2 (S42→S33→ . . . ).

When the timer value has exceeded the upper limit time T2, the values of ax, ay, and az at this time (at the time when it is determined that the current state is actually not a falling state) are stored as sx, sy, and sz (S43). Then the falling state signal described above is cancelled (S44), the timer is started again, and the same processing is performed (S43→S44→S31→ . . . ).

As described in steps S32 to S36, these values sx, sy, and sz are data on the basis of which fall detection determination based on ax, ay, and az is prohibited or the output of the fall detection determination result is prohibited next time.

In this manner, a stable state of rest in 1 G state is prevented from being erroneously determined as being a “falling state” after the first time.

Note that according to the first to third embodiments described above, since multiplication is not required, an operation load is low. As a result, hardware with a very simple architecture can be used to realize the embodiments.

### Fourth Embodiment

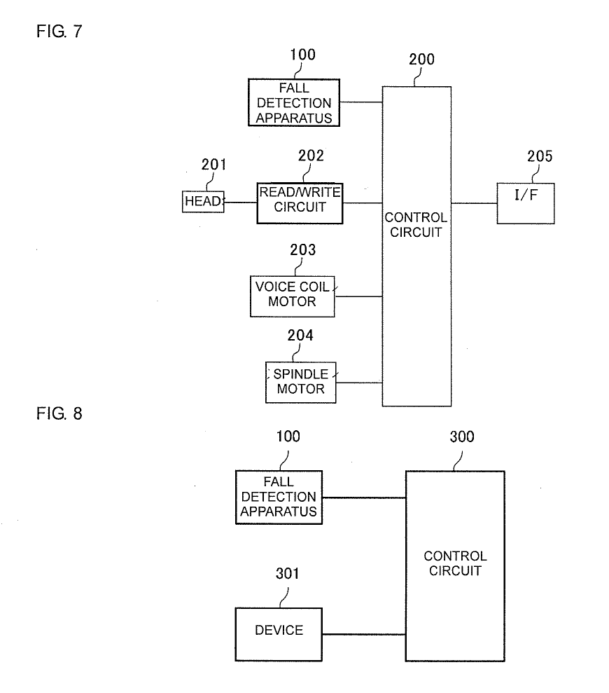

FIG. 7 is a block diagram of the configuration of a magnetic disk apparatus, such as a hard disk drive apparatus. Here, a read/write circuit 202 reads data from or writes data onto a track of a magnetic disk apparatus using a head 201. A control circuit 200 performs data read/write control through the read/write circuit 202 and communicates the read/write data with a host apparatus through an interface 205. The control circuit 200 controls a spindle motor 204 and a voice coil motor 203. The fall detection apparatus 100 has the configuration described in the first to fourth embodiments. The control circuit 200, through reading a fall detection signal output by the fall detection apparatus 100, controls the voice coil motor 203 to retract the head 201 to a retraction area during a falling state. In this manner, when a portable apparatus containing a hard disk drive falls, the head is retracted from the magnetic disk area to the retraction area before the portable apparatus collides with a floor or the ground, whereby damage caused by contact of the head 201 with the recording surface of the magnetic disk is prevented.

### Fifth Embodiment

FIG. 8 is a block diagram of the configuration of a mobile electronic apparatus containing a hard disk drive, such as a notebook PC or music/video reproduction apparatus. Here, the fall detection apparatus 100 has the configuration described in the first to fourth embodiments. A device 301 is a device that needs to be protected against a shock due to a collision during a fall and that allows processing for that protection to be performed. The device 301 may be, for example, a hard disk drive apparatus. A control circuit 300 controls the device 301 on the basis of the output signal of the fall detection apparatus 100. For example, upon receipt of a falling state signal from the fall detection apparatus 100, the control circuit 300 performs collision preparation control for the device 301 during falling.

### REFERENCE NUMBERS

60 acceleration sensor
72 A/D converter
74 controller
100 fall detection apparatus
205 interface
ax detected value obtained by an x-axis acceleration sensor
ay detected value obtained by a y-axis acceleration sensor
az detected value obtained by a z-axis acceleration sensor
ax0, ay0, az0 previous values
T continuation time
T1 continuation time
T2 upper limit time

1. A fall detection apparatus that detects a fall on the basis of an output signal of an acceleration sensor, the apparatus comprising:
an acceleration detector configured to obtain detected acceleration values in three axis directions orthogonal to one another; and
a fall determination output unit configured to obtain a determination value which is, among the detected acceleration values in the three axis directions obtained by the acceleration detector, a difference between the detected acceleration value corresponding to a reference axis direction and the detected acceleration value not corresponding to the reference axis direction, and configured to generate a falling state signal when a preliminary determination state in which the determination value is within a predetermined range continues for a predetermined continuation time or longer.

2. The fall detection apparatus according to claim 1, wherein the determination value is based on an absolute value of the difference between the detected acceleration value corresponding to the reference axis direction and the detected acceleration value not corresponding to the reference axis direction.

3. The fall detection apparatus according to claim 1, further comprising a falling state cancelling unit configured to cancel the falling state signal when the preliminary determination state continues for a time exceeding an upper limit time that is longer than the continuation time.

4. The fall detection apparatus according to claim 3, further comprising:
a steady state detected value storing unit configured to store the detected acceleration values for the three axis directions at the time when the falling state cancelling unit performs the cancellation; and
a prohibiting unit configured to prohibit fall detection determination or prohibit outputting of a fall determination result when the detected acceleration values for the three axis directions are substantially equal to the detected acceleration values stored in the steady state detected value storing unit.

5. The fall detection apparatus according to claim 4, wherein the detected acceleration values for the three axis directions are substantially equal to the detected acceleration values stored in the steady state detected value storing unit when the detected acceleration values are within a predetermined value range of the detected acceleration values stored in the steady state detected value storing unit.

6. A magnetic disk apparatus comprising:
the fall detection apparatus according to claim 1;
a head configured to perform data recording or reading from a magnetic disk; and
head retracting unit configured to retract the head to a retraction area when the fall detection apparatus generates the falling state signal.

7. The magnetic disk apparatus according to claim 6, wherein the head retracting unit includes:
a control circuit that reads the falling state signal generated by the fall detection apparatus; and
a voice coil motor controlled by the control circuit and operable to retract the head into the retraction area.

8. The magnetic disk apparatus according to claim 6, wherein the determination value is based on an absolute value of the difference between the detected acceleration value corresponding to the reference axis direction and the detected acceleration value not corresponding to the reference axis direction.

9. The magnetic disk apparatus according to claim 6, further comprising a falling state cancelling unit configured to cancel the falling state signal when the preliminary determination state continues for a time exceeding an upper limit time that is longer than the continuation time.

10. The magnetic disk apparatus according to claim 9, further comprising:
a steady state detected value storing unit configured to store the detected acceleration values for the three axis directions at the time when the falling state cancelling unit performs the cancellation; and
a prohibiting unit configured to prohibit fall detection determination or prohibit outputting of a fall determination result when the detected acceleration values for the three axis directions are substantially equal to the detected acceleration values stored in the steady state detected value storing unit.

11. The magnetic disk apparatus according to claim 10, wherein the detected acceleration values for the three axis directions are substantially equal to the detected acceleration values stored in the steady state detected value storing unit when the detected acceleration values are within a predetermined value range of the detected acceleration values stored in the steady state detected value storing unit.

12. A portable electronic apparatus including the fall detection apparatus according to claim 1 and a device configured to allow shock protection processing to be performed, the portable electronic apparatus comprising:
a shock protection processor configured to perform shock protection processing for the device when the fall detection apparatus generates the falling state signal.

13. The portable electronic apparatus according to claim 12, wherein the determination value is based on an absolute value of the difference between the detected acceleration value corresponding to the reference axis direction and the detected acceleration value not corresponding to the reference axis direction.

14. The portable electronic apparatus according to claim 12, further comprising a falling state cancelling unit configured to cancel the falling state signal when the preliminary determination state continues for a time exceeding an upper limit time that is longer than the continuation time.

15. The portable electronic apparatus according to claim 14, further comprising:
a steady state detected value storing unit configured to store the detected acceleration values for the three axis directions at the time when the falling state cancelling unit performs the cancellation; and
a prohibiting unit configured to prohibit fall detection determination or prohibit outputting of a fall determination result when the detected acceleration values for the three axis directions are substantially equal to the detected acceleration values stored in the steady state detected value storing unit.

16. The portable electronic apparatus according to claim 15, wherein the detected acceleration values for the three axis directions are substantially equal to the detected acceleration values stored in the steady state detected value storing unit when the detected acceleration values are within a predetermined value range of the detected acceleration values stored in the steady state detected value storing unit.
